(19) United States
(12) Patent Application Publication
(10) Pub. No.: US 2024/0349481 A1
(43) Pub. Date: Oct. 17, 2024

(54) SEMICONDUCTOR DEVICE INCLUDING MEMORY ELEMENT

(71) Applicant: Unisantis Electronics Singapore Pte. Ltd., Singapore (SG)

(72) Inventors: Nozomu HARADA, Tokyo (JP); Masakazu Kakumu, Tokyo (JP); Koji Sakui, Tokyo (JP)

(21) Appl. No.: 18/619,444

(22) Filed: Mar. 28, 2024

(30) Foreign Application Priority Data
Apr. 11, 2023 (WO) PCT/JP2023/014700

(51) Int. Cl. H10B 12/00; G11C 11/4096

(52) U.S. Cl. CPC H10B 12/20; G11C 11/4096

(57) ABSTRACT

A first impurity region that is connected to a first semiconductor pillar, a first gate insulating layer that is in contact with the first semiconductor pillar, a first gate conductor layer that is in contact with the first gate insulating layer, a first insulating layer, a second semiconductor pillar that has a recessed portion, a second insulating layer that is on the first gate conductor layer, a second gate insulating layer that is in contact with the second semiconductor pillar, a second gate conductor layer that is in contact with the second gate insulating layer, a third gate insulating layer that is in contact with the recessed portion, a third gate conductor layer that is in contact with the third gate insulating layer, and a second impurity region and a third impurity region that are on upper ends of an U-shape of the second semiconductor pillar are included.

### CROSS-REFERENCE TO RELATED APPLICATIONS

This application claims priority to PCT/JP2023/014700, filed Apr. 11, 2023, the entire content of which is incorporated herein by reference.

### BACKGROUND OF THE INVENTION

### 1. Field of the Invention

The present invention relates to a semiconductor device including a memory element.

### 2. Description of the Related Art

In recent years, there has been a need for the high integrity, high performance, low power consumption, and high functionality of semiconductor devices that use memory elements in the technological development of large scale integration (LSI).

As for a typical planar MOS transistor, a channel extends in a horizontal direction parallel with an upper surface of a semiconductor substrate. However, a channel of a SGT extends in a direction perpendicular to an upper surface of a semiconductor substrate (for example, Japanese Unexamined Patent Application Publication No. 2-188966, and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). For this reason, the SGT enables a semiconductor device to have a density higher than that of the planar MOS transistor. The SGT is used as a selection transistor, and consequently, the high integrity can be achieved, for example, for a dynamic random access memory (DRAM, see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)) to which a capacitor is connected, a phase change memory (PCM, see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp2b012b27 (2010)) to which a resistive change element is connected, a resistive random access memory (RRAM, see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “LOW Power and high Speed Switching of Ti-doped NiO ReRAM under the Unipolar Voltage Source of less than 3V,” IEDM (2007)), and a magneto-resistive random access memory (MRAM, see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)) that changes the direction of magnetic spin by using an electric current and that changes resistance. In addition, a memory cell (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)) includes a single MOS transistor that includes no capacitor, and a memory cell (see Md. Hasan Raza Ansari, Nupur Navlakha, Jae Yoon Lee, Seongjae Cho, “Double-Gate Junctionless 1T DRAM With Physical Barriers for Retention Improvement”, IEEE Trans, on Electron Devices vol. 67, pp. 1471-1479 (2020)) has a groove in which a carrier is stored and two gate electrodes. However, there is a problem in that a DRAM that includes no capacitor is greatly affected by coupling of a gate electrode from a word line of a floating body, and a voltage margin is not sufficiently maintained. A memory element includes a MOS transistor that writes and wipes data and a second channel that is connected below a first channel of the MOS transistor and that stores signal charges that correspond to “1”, “0” memory data (see, for example, US 2023/0077140 A1). The high integrity and high performance of the memory are needed. The present disclosure relates to a memory device using a semiconductor element that includes neither a resistive change element nor a capacitor and that can be achieved by using only a MOS transistor.

### SUMMARY OF THE INVENTION

A single-MOS-transistor memory cell that includes no capacitor has a problem in that capacitive coupling between a word line and a body that includes an element in a floating state and between a bit line and the body has a high degree and is directly transmitted as a noise to the body of a semiconductor substrate when the electric potential of the word line and the bit line is fluctuated during data reading or writing. As a result, a problem about misreading or mistakenly rewriting stored data arises, and it is difficult to put a single-transistor memory device that has no capacitor into practical use. It is necessary to solve the problems described above and to increase the density of the memory cell.

To solve the problems described above, a semiconductor device including a memory element according to a first invention includes a first semiconductor pillar that is erected above a substrate in a direction perpendicular to the substrate, a first impurity region that is connected to a bottom portion of the first semiconductor pillar, a first gate insulating layer that is in contact with a side surface of the first semiconductor pillar, a first gate conductor layer that is in contact with a side surface of the first gate insulating layer, a first insulating layer that insulates the first impurity region and the first gate conductor layer from each other, a second semiconductor pillar that has a recessed portion a vertical section of which has a U-shape and that includes a bottom portion that is in contact with a top of the first semiconductor pillar, a second insulating layer that is on the first gate conductor layer and that surrounds a vicinity of a boundary between the first semiconductor pillar and the second semiconductor pillar, a second gate insulating layer that is in contact with an outer side of the recessed portion of the second semiconductor pillar, a second gate conductor layer that is in contact with a side surface of the second gate insulating layer, a third gate insulating layer that is in contact with an inner side surface of the recessed portion of the second semiconductor pillar, a third gate conductor layer that is in contact with an inner side surface of the third gate insulating layer, and a second impurity region and a third impurity region that are in contact with respective upper ends of the U-shape of the second semiconductor pillar.

According to a second invention, the first gate conductor layer may be connected to a first plate line, the second gate conductor layer may be connected to a second plate line, the third gate conductor layer may be connected to a word line, the first impurity region may be connected to a control line, the second impurity region may be connected to a source line, and the third impurity region may be connected to a bit line, as for the semiconductor device including the memory element according to the first invention described above.

According to a third invention, in a plan view, a width of the first semiconductor pillar in a direction in which the second impurity region and the third impurity region are linked with each other may be greater than a width of the second semiconductor pillar, as for the first invention described above.

According to a fourth invention, the second gate conductor layer may be divided into two gate conductor layers in a horizontal direction, and the divided two gate conductor layers may be driven by applying a synchronous or asynchronous voltage thereto, as for the first invention described above.

According to a fifth invention, the first gate conductor layer may be divided into two gate conductor layers in the horizontal direction, and the divided two gate conductor layers may be driven by applying a synchronous or asynchronous voltage thereto, as for the fourth invention described above.

According to a sixth invention, in a plan view, the second gate conductor layer may surround an outer side of the second impurity region or the third impurity region, as for the first invention described above.

According to a seventh invention, in a plan view, the first gate conductor layer may overlap the second gate conductor layer, as for the sixth invention described above.

According to an eighth invention, the first impurity region may be isolated from an adjacent memory cell, and an impurity region a conductivity type of which is opposite that of the first impurity region may be in contact with a bottom of the first impurity region, as for the first invention described above.

According to a ninth invention, a voltage that is applied to the first to third impurity regions and the first to third gate conductor layers may be controlled, a data writing operation may be performed such that a majority carrier in electrons and holes that are generated in the second semiconductor pillar due to an impact ionization phenomenon or a gate induced drain leak current is mainly stored in the first semiconductor pillar by using an electric current that is caused to flow through the second semiconductor pillar between the second impurity region and the third impurity region, and a data wiping operation may be performed such that the majority carrier that is stored in the first semiconductor pillar is discharged from the first semiconductor pillar by using the voltage that is applied to the first to third impurity regions and the first to third gate conductor layers, as for the first invention described above.

According to a tenth invention, a voltage that is applied to the first to third impurity regions and the first to third gate conductor layers may be controlled, an electric current may be caused to flow from the first impurity region to the second impurity region or the third impurity region or both via the first semiconductor pillar and the second semiconductor pillar, a data writing operation may be performed such that a majority carrier in electrons and holes that are generated in the first and second semiconductor pillars due to an impact ionization phenomenon or a gate induced drain leak current is mainly stored in the first semiconductor pillar by using the electric current, and a data wiping operation may be performed such that the majority carrier that is stored in the first semiconductor pillar is discharged from the first semiconductor pillar by using the voltage that is applied to the first to third impurity regions and the first to third gate conductor layers, as for the first invention described above.

According to an eleventh invention, in a plan view, the first impurity region that is connected between memory cells aligned on a first line and that is aligned on the first line and an impurity region of a memory cell that is adjacent to the memory cells, that is connected in parallel with the first line, and that is aligned thereon are electrically isolated from each other and are synchronously or asynchronously driven, the impurity region corresponding to the first impurity region, as for the first invention described above.

### BRIEF DESCRIPTION OF THE DRAWINGS

FIG. 1A and FIG. 1B are diagrams for describing the structure of a semiconductor device that uses a memory element according to an embodiment.

FIG. 2AA, FIG. 2AB, and FIG. 2AC are diagrams for describing a data writing operation of the semiconductor device that uses the memory element according to the embodiment.

FIG. 2BA, FIG. 2BB, and FIG. 2BC are diagrams for describing another data writing operation of the semiconductor device that uses the memory element according to the embodiment.

FIG. 3A, FIG. 3B, and FIG. 3C are diagrams for describing a data wiping operation of the semiconductor device that uses the memory element according to the present embodiment.

FIG. 4A and FIG. 4B are diagrams for describing the structure of the semiconductor device that uses the memory element according to the present embodiment.

FIG. 5A and FIG. 5B are diagrams for describing the structure of the semiconductor device that uses the memory element according to the present embodiment.

FIG. 6A and FIG. 6B are diagrams for describing the structure of the semiconductor device that uses the memory element according to the present embodiment.

### DESCRIPTION OF THE PREFERRED EMBODIMENTS

A semiconductor device that uses a memory element according to an embodiment of the present invention will now be described with reference the drawings.

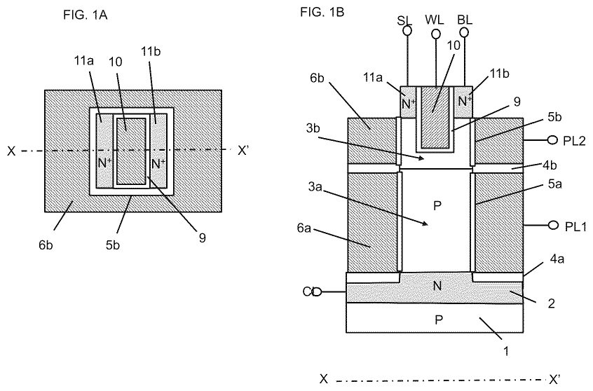

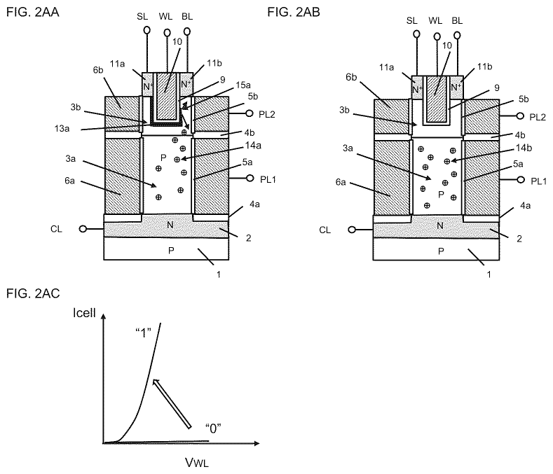

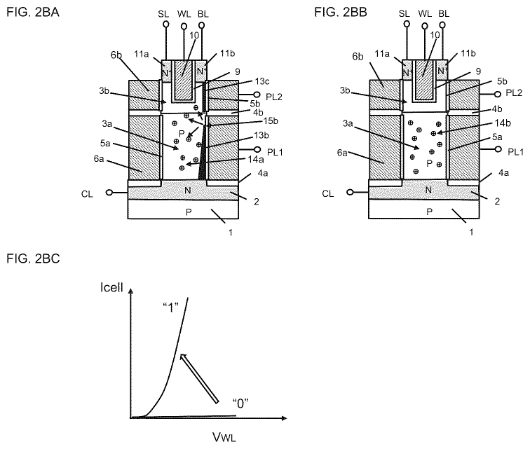

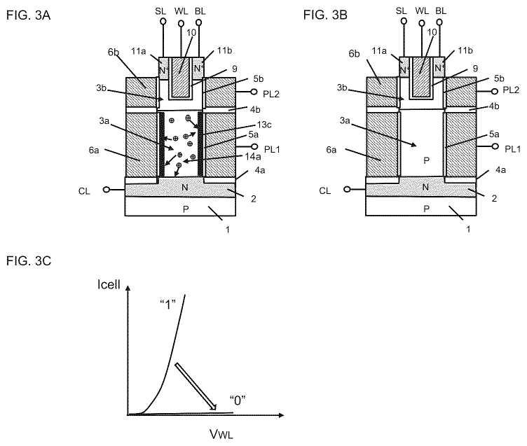

The structure of a memory cell according to the present embodiment will be described with reference to FIG. 1A and FIG. 1B. A mechanism of the memory cell according to the present embodiment for writing data will be described with reference to FIG. 2AA to FIG. 2AC. Another mechanism according to the present embodiment for writing data will be described with reference to FIG. 2BA to FIG. 2BC. A mechanism of the memory cell according to the present embodiment for wiping data will be described with reference to FIG. 3A to FIG. 3C. As for an actual memory device, multiple memory cells are arranged in a two-dimensional array on a substrate.

FIG. 1A illustrates a plan view of an upper surface of the memory cell. FIG. 1B illustrates the structure of a vertical section of the memory cell taken along a line X-X′ in FIG. 1A. On a P-layer substrate 1 (an example of a “substrate” in the claims) is an N-layer 2 (an example of a “first impurity region” in claims) that contains donor impurities (a semiconductor region that contains donor impurities is referred to below as an “N-layer”). On the N-layer 2 is a first pillar P-layer 3a (an example of a “first semiconductor pillar” in the claims) that contains acceptor impurities (a semiconductor region that contains acceptor impurities is referred to below as a “P-layer”). An insulating layer 4a (an example of a “first insulating layer” in the claims) covers an upper surface of the N-layer 2 along the outer periphery of the first pillar P-layer 3a. A first gate insulating layer 5a (an example of a “first gate insulating layer” in the claims) is in contact with a side surface of the first pillar P-layer 3a. A first gate conductor layer 6a (an example of a “first gate conductor layer” in the claims) is in contact with a side surface of the first gate insulating layer 5a. On the first gate insulating layer 5a and the first gate conductor layer 6a is a second insulating layer 4b (an example of a “second insulating layer” in the claims). On the first pillar P-layer 3a is a second pillar P-layer 3b (an example of a “second semiconductor pillar” in the claims). As illustrated in FIG. 1B, the second pillar P-layer 3b has a vertical section that has a U-shape. A second gate insulating layer 5b (an example of a “second gate insulating layer” in the claims) is in contact with an outer side surface of the second pillar P-layer 3b. A second gate conductor layer 6b (an example of a “second gate conductor layer” in the claims) is in contact with the second gate insulating layer 5b. Along an edge of the second pillar P-layer 3b is an N⁺-layer 11a (an example of a “second impurity region” in the claims) that contains donor impurities at a high concentration (a semiconductor region that contains donor impurities at a high concentration is referred to below as an “N⁺-layer”). Along another edge of the second pillar P-layer 3b opposite the N⁺-layer 11a is an N⁺-layer 11b (an example of a “third impurity region” in the claims). Along an inner side surface and a bottom surface of a recessed portion that has a U-shape on the second pillar P-layer 3b is a third gate insulating layer 9 (an example of a “third gate insulating layer” in the claims) that has a vertical section similarly having a U-shape and that is in contact therewith. A third gate conductor layer 10 (an example of a “third gate conductor layer” in the claims) is in contact with an inner side of a recessed portion on the third gate insulating layer 9.

The N⁺-layer 11a is connected to a source line SL. The N⁺-layer 11b is connected to a bit line BL. The first gate conductor layer 6a is connected to a first plate line PL1. The second gate conductor layer 6b is connected to a second plate line PL2. The third gate conductor layer 10 is connected to a word line WL. The N-layer 2 is connected to a control line CL. The electric potential of the source line SL, the bit line BL, the first plate line PL1, the second plate line PL2, the word line WL, and the control line CL is operated, and consequently, a memory operation is performed. As for the actual memory device, a large number of the memory cells are arranged in a two-dimensional array on the P-layer substrate 1.

A data writing operation of the memory cell according to the embodiment of the present invention will be described with reference to FIG. 2AA to FIG. 2AC. As illustrated in FIG. 2AA, a MOS transistor that includes the N⁺-layer 11a that serves as a source, the N⁺-layer 11b that serves as a drain, the third gate insulating layer 9 that serves as a gate insulating layer, the third gate conductor layer 10 that serves as a gate, and the second pillar P-layer 3b that serves as a channel is formed in the memory cell. The MOS transistor is operated in a saturation region. For example, a voltage of 0 V is applied to the control line CL, the source line SL, the first plate line PL1, and the second plate line PL2, a voltage of 3 V is inputted into the bit line BL, and a voltage of 1.5 V is inputted into the word line WL. Consequently, an inversion layer 13a is formed in the second pillar P-layer 3b right below the third gate insulating layer 9, and a pinch-off point 15a is formed.

As a result, as illustrated in FIG. 2AA, an electric field is maximized in the vicinity of a boundary region between the pinch-off point 15a and the N⁺-layer 11b, and an impact ionization phenomenon occurs in this region. The impact ionization phenomenon causes electrons that are accelerated from the N⁺-layer 11a to the N⁺-layer 11b to collide with an Si lattice, and the kinetic energy thereof generates electron-hole pairs. Holes 14a that are generated diffuse due to the concentration gradient thereof toward a region in which the concentration of the holes reduces. Some of generated electrons flow into the third gate conductor layer 10, but most of these flow into the N⁺-layer 11b that is connected to the bit line BL. The holes 14a may be generated by causing a gate induced drain leakage (GIDL) electric current to flow instead of causing the impact ionization phenomenon described above to occur (see, for example, E. Yoshida, T, Tanaka, “A Capacitorless 1T-DARM Technology Using Gate-Induced Drain-Leakage (GIDL) Current for Low-Power and High-Speed Embedded Memory”, IEEE Trans, on Electron Devices vol. 53, pp. 692-697 (2006)).

FIG. 2AB illustrates holes 14b that are stored in the first pillar P-layer 3a when a voltage of 0 V is applied to the word line WL, the bit line BL, the first plate line PL1, the second plate line PL2, and the source line SL right after data writing. At the beginning, the concentration of the generated holes is high in the region of the second pillar P-layer 3b, and the holes diffuse and move toward the first pillar P-layer 3a due to the concentration gradient thereof and stored. As a result, the concentration of the holes in the first pillar P-layer 3a is higher than the concentration of the holes in the second pillar P-layer 3b. The first pillar P-layer 3a that substantially corresponds to a substrate for the MOS transistor that includes the third gate conductor layer 10 because the first pillar P-layer 3a and the second pillar P-layer 3b are electrically connected to each other is charged at positive bias. The holes 14b move toward the N⁺-layers 11a and 11b or the N-layer 2, and some of these are gradually recombined with the electrons, but the threshold voltage of the MOS transistor that includes the third gate conductor layer 10 reduces due to the positive substrate bias effect of the holes 14b that are mainly stored in the first pillar P-layer 3a. Consequently, as illustrated in FIG. 2AC, the threshold voltage of the MOS transistor that includes the third gate conductor layer 10 to which the word line WL is connected reduces. This writing state is assigned to logical memory data “1”.

Another data writing operation of the memory cell that differs from that in FIG. 2AA to FIG. 2AC will be described with reference to FIG. 2BA to FIG. 2BC. As illustrated in FIG. 2BA, a dual gate MOS transistor includes the N-layer 2 that serves as a source, the N⁺-layer 11b that serves as a drain, the first gate insulating layer 5a and the second gate insulating layer 5b that serve as gate insulating layers, the first gate conductor layer 6a and the second gate conductor layer 6b that serve as gates, and the first pillar P-layer 3a and the second pillar P-layer 3b that serve as channels. A voltage of, for example, 0 V is applied to the word line WL, no electric current flows between the source line SL and the bit line BL. An electric current is caused to flow between the control line CL and the bit line BL. In this case, a MOS transistor region with the first pillar P-layer 3a that is surrounded by the first gate conductor layer 6a serving as a channel is operated in the saturation region. A MOS transistor region with the second pillar P-layer 3b that is surrounded by the second gate conductor layer 6b serving as a channel is operated in a linear region. Consequently, an inversion layer 13b that has a pinch-off point 15b is formed in a surface layer of the first pillar P-layer 3a near the N⁺-layer 11b in a plan view. At the same time, an inversion layer 13c is formed in a surface layer of the second pillar P-layer 3b near the N⁺-layer 11b. The inversion layer 13c seemingly operates as a drain. An electric field is maximized near the pinch-off point 15b. Consequently, the first pillar P-layer 3a near the pinch-off point generates holes and electrons due to the impact ionization phenomenon as in FIG. 2AA to FIG. 2AC.

Subsequently, as illustrated in FIG. 2BB, the same operation as in FIG. 2AB is performed, and consequently, the holes 14b are mainly stored in the first pillar P-layer 3a. As illustrated in FIG. 2BC, the threshold voltage reduces due to the positive substrate bias effect of the holes 14b that are stored. This writing state is assigned to the logical memory data “1”. As for the writing operation, a distance at which the electrons that enter from the N-layer 2 for impact ionization travel can be increased by increasing the length of the first gate conductor layer 6a in a perpendicular direction unlike the method in FIG. 1A and FIG. 1B. This enables a writing voltage to be reduced. Conditions in which the bit line BL, the source line SL, the word line WL, the first plate line PL1, and the second plate line PL2 operate illustrated in FIG. 2AA to FIG. 2AC and FIG. 2BA to FIG. 2BC are examples for the writing operations and may be other conditions in which the writing operations can be performed. An electric current path for the impact ionization may be between the N-layer 2 and the N⁺-layer 11a.

A mechanism for a data wiping operation will now be described with reference to FIG. 3A to FIG. 3C. The holes 14a that are generated due to the impact ionization in a previous cycle before the data wiping operation are mainly stored in the first pillar P-layer 3a. During the wiping operation, as illustrated in FIG. 3A, a voltage of, for example, 2 V is applied to the first plate line PL1, and the inversion layer 13c is formed in the surface layer of the first pillar P-layer 3a. A voltage of, for example, −0.5 V is applied to the control line CL, and a PN junction between the N-layer 2 and the first pillar P-layer 3a is at forward bias. Consequently, the holes 14a are recombined with the electrons in the inversion layer 13c and the N-layer 2 over time and are discharged. Consequently, as illustrated in FIG. 3C, the threshold voltage of the MOS transistor is higher than that when “1” is written and returns to the initial state. This state is assigned to logical memory data “0”.

In FIG. 3A to FIG. 3C, a voltage of, for example, 2 V is applied to the second plate line PL2, and a voltage of, for example, −0.5 V is applied to the source line SL or the bit line BL or both. This enables an inversion layer to be formed in the outer side surface of the second pillar P-layer 3b and enables the holes 14a to be discharged. In this case, the N⁺-layer 11a, the N⁺-layer 11b, and the N-layer 2 can be electrically connected to each other, and a time for wiping data can be reduced. Voltage conditions of the data wiping operation described above are examples for the data wiping operation and may be other voltage conditions in which the data wiping operation can be performed.

In FIG. 1A and FIG. 1B, the N-layer 2 that is connected to the control line CL is connected to the N-layer of an adjacent memory cell. The N-layer 2 may be formed only at a bottom portion of the first pillar P-layer 3a. In this case, the voltage of the N-layer 2 is applied by using the voltage that is applied to the P-layer substrate 1.

The present embodiment has the following features.

(1) According to the present embodiment, the second gate insulating layer 5b and the second gate conductor layer 6b surround the outer side surface of the second pillar P-layer 3b. The second gate conductor layer 6b exerts an effect of electrically shielding a wiring layer for the source line SL, the word line WL, and the bit line BL and the first gate conductor layer 6a from each other. The effect of electrically shielding contributes to a reduction in a variation in the electric potential of the first pillar P-layer 3a due to capacitive coupling between the source line SL and the first gate conductor layer 6a, between the word line WL and the first gate conductor layer 6a, and between the bit line BL and the first gate conductor layer 6a, which acts when the adjacent memory cell is accessed. The reduction in the variation in the electric potential of the first pillar P-layer 3a leads to stably maintaining the holes 14b in the first pillar P-layer 3a in the state of the data “1” and prevents holes from entering the first pillar P-layer 3a from the outside in the state of the data “0”. This contributes to preventing disturbance failure where a cell to which “1” is written exhibits “0” due to the operation of another cell, or a cell to which “0” is written exhibits “1” due to the operation of another cell (see, for example, H. Miyagawa et al. “Metal-Assisted Solid-Phase Crystallization Process for Vertical Monocrystalline Si Channel in 3D Flash Memory”, IEDM19 digest paper, pp. 650-653 (2019)). As for a design for increasing the integrity of the memory cell with the source and drain of the adjacent memory cell shared, the effect of electrically shielding of the second gate conductor layer 6b is effectively exerted.

(2) According to the present embodiment, as illustrated in FIG. 2BA to FIG. 2BC, the holes 14a can be formed due to the impact ionization phenomenon in the dual gate MOS transistor in which the N-layer 2 serves as the source, the N⁺-layer 11b serves as the drain, and the first and second gate conductor layers 6a and 6b serve as the gates. The length of the channel for obtaining the kinetic energy that is needed for the electrons that exit the source to collide with an Si atoms lattice to generate the electron-hole pairs is needed to generate the holes 14a by using the impact ionization phenomenon. The length of the channel that is needed to generate the holes 14a by using the impact ionization phenomenon is achieved by adjusting the height of the first pillar P-layer 3a without reducing the planar area of the memory cell.

(3) According to the present embodiment, the second gate conductor layer 6b is connected to the second plate line PL2 outside the second gate insulating layer 5b, and this enables not only the inversion layer 13c in the side surface of the first pillar P-layer 3a but also the inversion layer in the outer side surface of the second pillar P-layer 3b to be formed as described with reference to FIG. 3A to FIG. 3C. This enables the holes 14b to be discharged from not only the inversion layer 13c that is connected to the N-layer 2 but also the inversion layer that is connected to the N⁺-layers 11a and 11b during the data wiping operation. This enables the speed of the data wiping operation to be increased. As for the MOS transistor with the second pillar P-layer 3b that has a U-shape between the N⁺-layers 11a and 11b serving as the channel, if an insulating layer surrounds the outside of the second pillar P-layer 3b, it is difficult to form the inversion layer in the outer side surface of the second pillar P-layer 3b.

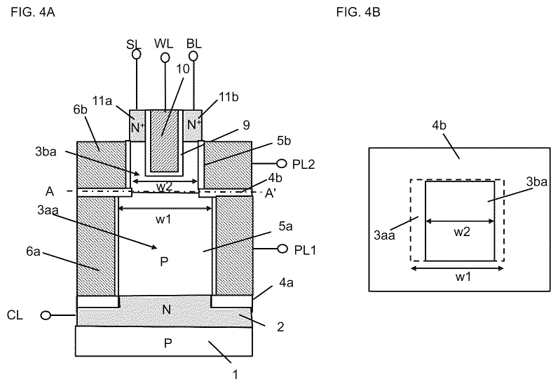

The structures of memory cells according to other embodiments will be described with reference to FIG. 4A to FIG. 6B.

The structure of a memory cell according to another embodiment is illustrated in FIG. 4A and FIG. 4B. FIG. 4A illustrates a vertical section of the memory cell. FIG. 4B illustrates a horizontal section horizontally taken along a line A-A′ in FIG. 4A. As illustrated in FIG. 4A, the width w1 of a first pillar P-layer 3aa is greater than the width w2 of a second pillar P-layer 3ba. As illustrated in FIG. 4B, both edges of the first pillar P-layer 3aa and both edges of the second pillar P-layer 3ba in a depth direction in FIG. 4A along the line A-A′ match each other. This enables the first pillar P-layer 3aa to cover a bottom portion of the second pillar P-layer 3ba with certainty and enables the volume of the first pillar P-layer 3aa in which holes for the data “1” are stored to be increased.

In FIG. 4A and FIG. 4B, the first pillar P-layer 3aa extends to both sides of the second pillar P-layer 3ba but may extend to only a single side.

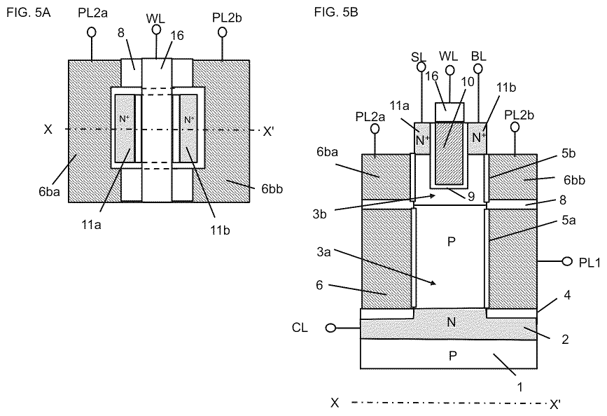

The structure of a memory cell according to another embodiment is illustrated in FIG. 5A and FIG. 5B. FIG. 5A illustrates a plan view of the memory cell. FIG. 5B illustrates a sectional view taken along a line X-X′ in FIG. 5A. A wiring metal layer 16 that is in contact with the third gate conductor layer 10 extends in a direction perpendicular to the line X-X′ in a plan view. The second gate conductor layer 6b is connected to the plate line PL in FIG. 1A and FIG. 1B but is divided into second gate conductor layers 6ba and 6bb in FIG. 5A, and these extend in the direction perpendicular to the line X-X′. The second gate conductor layers 6ba and 6bb extend in the direction perpendicular to the line X-X′ in a plan view as in the wiring metal layer 16. The second gate conductor layer 6ba covers a portion of the second gate insulating layer 5b at which the N⁺-layer 11a is present. The second gate conductor layer 6bb covers a portion of the second gate insulating layer 5b at which the N⁺-layer 11b is present. The second gate conductor layer 6ba is connected to a plate line PL2a. The second gate conductor layer 6bb is connected to a plate line PL2b. An insulating layer 8 is between the first gate conductor layer 6 and the second gate conductor layers 6ba and 6bb.

The second gate conductor layers 6ba and 6bb that are connected to the plate lines PL2a and PL2b may be shared with an adjacent memory cell. A first gate conductor layer 6 may be divided into two pieces as in the second gate conductor layers 6ba and 6bb, and these may be connected to respective individual plate lines. Also this basically enables the same memory operation as that of the memory cell illustrated in FIG. 1A to FIG. 3C to be performed.

According to the present embodiment, the second gate conductor layer 6ba can be used as an electrical shield electrode, and the second gate conductor layer 6bb can be used as a data writing electrode.

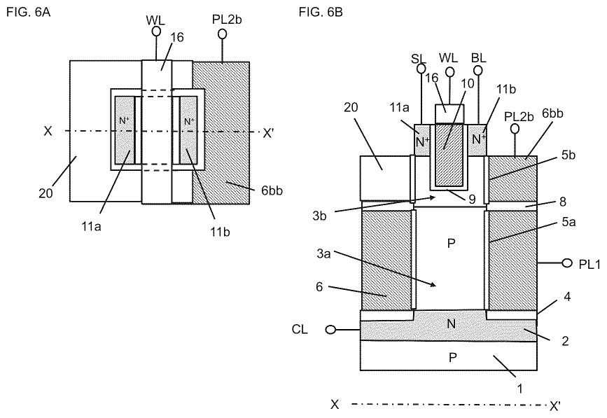

The structure of a memory cell according to another embodiment will be described with reference to FIG. 6A and FIG. 6B. FIG. 6A illustrates a plan view of the memory cell. FIG. 6B illustrates a sectional view taken along a line X-X′ in FIG. 6A. As for the memory cell, as illustrated in FIG. 6A and FIG. 6B, the second gate conductor layer 6ba that is connected to the second plate line PL2a in FIG. 5A and FIG. 5B is not provided, but an insulating layer 20 is provided. Also this basically enables the same memory operation as that of the memory cell illustrated in FIG. 1A to FIG. 3C to be performed.

In FIG. 1A and FIG. 1B, the first gate insulating layer 5a and the second gate insulating layer 5b may be connected to each other and may be composed of the same insulating material. The same is true for the other embodiments.

In FIG. 1A and FIG. 1B, the first gate insulating layer 5a and the second gate insulating layer 5b may cover a portion of the first pillar P-layer 3a in a plan view. Similarly, the first gate conductor layer 6a and the second gate conductor layer 6b may cover a portion of the first gate insulating layer 5a and a portion of the second gate insulating layer 5b. The same is true for the other embodiments.

In FIG. 1A and FIG. 1B, as for the N-layer 2, an upper portion may be formed in a region in which a donor concentration is low, and a lower portion may form a region in which the donor concentration is high. In a plan view, the area of a portion of the N-layer 2 that is in contact with the bottom portion of the first pillar P-layer 3a may be smaller than the area of the bottom portion of the first pillar P-layer 3a. The same is true for the other embodiments.

In FIG. 1A and FIG. 1B, a P-well structure or a silicon on insulator (SOI) substrate may be used instead of the P-layer substrate 1. The same is true for the other embodiments.

In FIG. 1A and FIG. 1B, the first gate conductor layer 6a, the second gate conductor layer 6b, and the third gate conductor layer 10 may be conductor layers such as metal, alloy or highly doped semiconductor layers. The first gate conductor layer 6a, the second gate conductor layer 6b, and the third gate conductor layer 10 may include multiple conductor layers. The first gate conductor layer 6a, the second gate conductor layer 6b, and the third gate conductor layer 10 may be formed by using conductor layers that have different work functions. The same is true for the other embodiments.

In FIG. 1A and FIG. 1B, the position of the boundary between the N-layer 2 and the first pillar P-layer 3a is preferably the same as or higher than the position of the bottom surface of the first gate conductor layer 6a in the perpendicular direction. The bottom surface of the first gate conductor layer 6a may overlap the concentration distribution of the donor impurities in the N-layer 2. The same is true for the other embodiments.

The memory may be operated with the N⁺-layer 11a and the N⁺-layer 11b formed by using a P⁺-layer in which a hole corresponds to a majority carrier and with a carrier for writing being an electron. The same is true for the other embodiments.

In FIG. 1A and FIG. 1B, the shapes of the vertical sections of the first and second pillar P-layers 3a and 3b are illustrated as rectangular shapes but may be trapezoidal shapes. The same is true for the other embodiments. The horizontal sections of the first and second pillar P-layers 3a and 3b may have a square shape or a rectangular shape. The same is true for the other examples.

In FIG. 1A and FIG. 1B, the N-layer 2 is illustrated so as to be connected to the adjacent memory cell but may be present at only the bottom portion of the first pillar P-layer 3a. For example, in a plan view, the N-layers 2 of memory cells that are aligned on a line may be connected to each other and may be electrically isolated from the N-layer of a memory cell that is adjacent to the N-layers 2 connected to each other and that is connected on the line, and these may be synchronously or asynchronously driven. The same is true for the other examples. In this case, an N⁺-layer that contains donor impurities at a high concentration may be in contact with the N-layer 2, and a metal later or an alloy layer may be in contact with the N⁺-layer.

In the case where the N-layer 2 illustrated in FIG. 1A and FIG. 1B is connected to the adjacent memory cell and is connected to the control line CL, a conductor layer may be provided on a portion or the entire surface of the N-layer 2 along the outer periphery of the first pillar P-layer 3a in a plan view. The same is true for the other examples.

In FIG. 1A and FIG. 1B, the first pillar P-layer 3a and the second pillar P-layer 3b may be formed in a manner in which material layers that are to be the first and second gate conductor layers 6a and 6b and insulating layers above, below, and between these are stacked into a layered structure, a hole is subsequently made through these layers, and a selective epitaxial crystal growth method or a metal induced lateral crystallization (MILC) method, for example is used (see, for example, H. Miyagawa et al. “Metal-Assisted Solid-Phase Crystallization Process for Vertical Monocrystalline Si Channel in 3D Flash Memory”, IEDM19 digest paper, pp. 650-653 (2019)). The first and second gate conductor layers 6a and 6b may be formed in a manner in which a dummy gate material that is first formed is etched, and the first and second gate conductor layers 6a and 6b are subsequently embedded in a created space. The same is true for the other embodiments.

In FIG. 1A and FIG. 1B, the first gate conductor layer 6a and the second gate conductor layer 6b may be divided into multiple pieces in the horizontal or perpendicular direction, and these may be synchronously or asynchronously driven. Also this enables the memory operation to be normally performed. The same is true for the other embodiments.

In FIG. 1A and FIG. 1B, a lightly doped drain (LDD) region may be provided between the N⁺-layers 11a and 11b and the second pillar P-layer 3b. The same is true for the other embodiments.

In FIG. 1A and FIG. 1B, a combination of P⁺ poly (a work function of 5.15 eV) and N⁺ poly (a work function of 4.05 eV) may be used as a combination of the first and second gate conductor layers 6a and 6b and the third gate conductor layer 10. Metal, meatal nitrides, alloys (including silicide) thereof, or a laminated structure thereof such as Ni (a work function of 5.2 eV) and N⁺ poly, Ni and W (a work function of 4.52 eV), and Ni and TaN (a work function of 4.0 eV)/W/TiN (a work function of 4.7 eV) may be used for the combination. The first and second gate conductor layers 6a and 6b and the third gate conductor layer 10 may be formed by using the same conductor layer, and the data writing operation described above may be performed by changing a drive voltage. The same effect can be obtained in a manner in which the first and second gate conductor layers 6a and 6b and the third gate conductor layer 10 that have the same work function are used, and the voltage that is applied to the bit line BL, the word line WL, and the source line SL is changed. The same is true for the other embodiments.

As for the present invention, various embodiments and modifications can be made without departing from the range and spirit of the present invention in a broad sense. The embodiments are described above to describe examples of the present invention and do not limit the range of the present invention. The examples described above and modifications can be freely combined. One obtained by removing some of components according to the embodiments described above as needed is within the range of the technical idea of the present invention.

The use of a semiconductor device that includes a memory element according to the present invention enables a semiconductor device that has high performance and high integrity to be provided.

What is claimed is:

1. A semiconductor device including a memory element, comprising:
a first semiconductor pillar that is erected above a substrate in a direction perpendicular to the substrate;
a first impurity region that is connected to a bottom portion of the first semiconductor pillar;
a first gate insulating layer that is in contact with a side surface of the first semiconductor pillar;
a first gate conductor layer that is in contact with a side surface of the first gate insulating layer;
a first insulating layer that insulates the first impurity region and the first gate conductor layer from each other;
a second semiconductor pillar that has a recessed portion a vertical section of which has a U-shape and that includes a bottom portion that is in contact with a top of the first semiconductor pillar;
a second insulating layer that is on the first gate conductor layer and that surrounds a vicinity of a boundary between the first semiconductor pillar and the second semiconductor pillar;
a second gate insulating layer that is in contact with an outer side surface of the recessed portion of the second semiconductor pillar;
a second gate conductor layer that is in contact with a side surface of the second gate insulating layer;
a third gate insulating layer that is in contact with an inner side surface of the recessed portion of the second semiconductor pillar;
a third gate conductor layer that is in contact with a side surface of the third gate insulating layer; and
a second impurity region and a third impurity region that are in contact with respective upper ends of the U-shape of the second semiconductor pillar.

2. The semiconductor device according to claim 1, wherein
the first gate conductor layer is connected to a first plate line,
the second gate conductor layer is connected to a second plate line,
the third gate conductor layer is connected to a word line,
the first impurity region is connected to a control line,
the second impurity region is connected to a source line, and
the third impurity region is connected to a bit line.

3. The semiconductor device according to claim 1, wherein
in a plan view, a width of the first semiconductor pillar in a direction in which the second impurity region and the third impurity region are linked with each other is greater than a width of the second semiconductor pillar.

4. The semiconductor device according to claim 1, wherein
the second gate conductor layer is divided into two gate conductor layers in a horizontal direction, and the divided two gate conductor layers are driven by applying a synchronous or asynchronous voltage thereto.

5. The semiconductor device according to claim 4, wherein
the first gate conductor layer is divided into two gate conductor layers in the horizontal direction, and the divided two gate conductor layers are driven by applying a synchronous or asynchronous voltage thereto.

6. The semiconductor device according to claim 1, wherein
in a plan view, the second gate conductor layer surrounds an outer side of the second impurity region or the third impurity region.

7. The semiconductor device according to claim 6, wherein
in a plan view, the first gate conductor layer overlaps the second gate conductor layer.

8. The semiconductor device according to claim 1, wherein
the first impurity region is isolated from an adjacent memory cell, and
an impurity region a conductivity type of which is opposite that of the first impurity region is in contact with a bottom of the first impurity region.

9. The semiconductor device according to claim 1, wherein
a voltage that is applied to the first to third impurity regions and the first to third gate conductor layers is controlled,
a data writing operation is performed such that a majority carrier in electrons and holes that are generated in the second semiconductor pillar due to an impact ionization phenomenon or a gate induced drain leak current is mainly stored in the first semiconductor pillar by using an electric current that is caused to flow through the second semiconductor pillar between the second impurity region and the third impurity region, and
a data wiping operation is performed such that the majority carrier that is stored in the first semiconductor pillar is discharged from the first semiconductor pillar by using the voltage that is applied to the first to third impurity regions and the first to third gate conductor layers.

10. The semiconductor device according to claim 1, wherein
a voltage that is applied to the first to third impurity regions and the first to third gate conductor layers is controlled,
an electric current is caused to flow from the first impurity region to the second impurity region or the third impurity region or both via the first semiconductor pillar and the second semiconductor pillar,
a data writing operation is performed such that a majority carrier in electrons and holes that are generated in the first and second semiconductor pillars due to an impact ionization phenomenon or a gate induced drain leak current is mainly stored in the first semiconductor pillar by using the electric current, and
a data wiping operation is performed such that the majority carrier that is stored in the first semiconductor pillar is discharged from the first semiconductor pillar by using the voltage that is applied to the first to third impurity regions and the first to third gate conductor layers.

11. The semiconductor device according to claim 1, wherein
in a plan view, the first impurity region that is connected between memory cells aligned on a first line and that is aligned on the first line and an impurity region of a memory cell that is adjacent to the memory cells, that is connected in parallel with the first line, and that is aligned thereon are electrically isolated from each other and are synchronously or asynchronously driven, the impurity region corresponding to the first impurity region.
